(19) United States
(12) Patent Application Publication
(10) Pub. No.: US 2007/0241766 A1
(43) Pub. Date: Oct. 18, 2007

(54) Semiconductor integrated circuit

(76) Inventors: Tsunetomo Kamitai, Kyoto (JP); Katsuya Fujimura, Kyoto (JP); Daiju Kitamoto, Osaka (JP); Hirofumi Taguchi, Osaka (JP); Kasumi Hamaguchi, Osaka (JP); Takahisa Tokushige, Kyoto (JP)

Correspondence Address: MCDERMOTT WILL & EMERY LLP, 600 13TH STREET, NW, WASHINGTON, DC, 20005-3096, US

(21) Appl. No.: 11/783,128

(22) Filed: Apr. 6, 2007

(30) Foreign Application Priority Data
Apr. 13, 2006 (JP) 2006-110594

(51) Int. Cl. G01R 31/02

(52) U.S. Cl. 324/763

(57) ABSTRACT

A semiconductor integrated circuit includes a wiring capable of connecting a plurality of chips on a wafer and has a configuration which is capable of cutting the wiring electrically and which allows all the chips to be tested at one time. Specifically, an exclusive test circuit region capable of being shared for testing the plurality of chips is formed on the wafer, and a test circuit is removed from each chip. Terminals of the chips and a terminal of the test circuit are connected through a wiring on the wafer or a device outside the wafer to enable a general test to be performed in burn-in.

### BACKGROUND OF THE INVENTION

The present invention relates to a semiconductor integrated circuit and particularly relates to a test for a wafer-level semiconductor integrated circuit.

Semiconductor integrated circuits are subjected to various tests, such as a probe test in a wafer level, a final test after packaged with the wafer divided, a burn-in test for degrading transistors that are going to be out of order by operating the transistors in adverse environment, a test thereafter, and so on.

In the probe test and the final test, semiconductor integrated circuits packaged or on a wafer are tested one by one with the use of a test circuit included in each of the semiconductor integrated circuits. A recent increase in scale of semiconductor integrated circuits, however, extends a test time to increase the rate of the test cost occupying the product cost.

Further, in the burn-in test, the semiconductor integrated circuits are operated under a condition of high temperature, high voltage, high humidity, and the like for sorting out initial defective transistors. This test had been performed on semiconductor integrated circuits packaged with plastic resin and are now being performed thereon in a wafer-level. The burn-in test can roughly sort out initial defectives in general, and therefore, all semiconductor integrated circuits are subjected to the burn-in test especially in the miniaturization process. Though it takes several hours to several tens hours for the burn-in test, a test pattern to be input for operating the several hundreds to several thousands semiconductor integrated circuits on a wafer one by one is simple.

FIG. 31 shows a conventional burn-in test method. As shown in FIG. 31, multiple chips 2 are formed on a wafer 1, and the same test pattern is input to each of the chips 2 from a burn-in device. The burn-in device has a limited number of signals usable for inputting and outputting a test pattern. For this reason, a smaller number of input/output terminals of the chips are determined as burn-in test terminals, and the test pattern is applied only to the determined terminals. With a smaller number of usable terminals, the test itself cannot prove whether or not all of the semiconductor integrated circuits operate normally. Further, the test circuit, which is unnecessary in a normal operation, is included in each chip, leading to an undesired increase in chip cost.

Referring to a conventional technique for efficiently applying a test signal by a burn-in device of which usable terminals are limited in number, a wiring is lead out to an isolation region from each of the multiple chips formed on a wafer and is connected to the burn-in device (see Japanese Patent Application Laid Open Publication No. 6-69298A).

This conventional technique, however, invites an increase in an enormous number of wirings for the test to increase the wiring length and the wiring area in the isolation region, and therefore, problems, such as signal delay, reduction in the number of chips that can be formed on a wafer, which is accompanied by an increase in area of the isolation region, and the like are involved to make the technique to be impractical. Further, the wirings connected to an external terminal in the isolation region are not subjected to processing after chip division, involving problems in quality and the like. In addition, all chips on the wafer are tested at one time, which requires enormous electric power, inviting problems that a general burn-in device cannot perform the test, and the like.

Each of the chips includes the same test circuit. In association with a recent increase in scale of semiconductor integrated circuits, the area of the test circuit occupies several percentages out of the chip area, presenting a significant task of reducing in area of the test circuit. Moreover, the test circuits in all the chips have the same function, which means irrational configuration of the wafer as a whole.

Though the burn-in requires several hours, transistors repeat ON/OFF operation purposelessly during the time, which means ineffective use of time.

The increase in scale of the semiconductor integrated circuits leads to an increase in test time. Therefore, reduction in test time, in area of the test circuit, and the like is a key to increase in profitability of the chips.

### SUMMARY OF THE INVENTION

The present invention has been made in view of the foregoing and has its object of providing a semiconductor integrated circuit of which test cost is reduced by performing a wafer-level test in burn-in.

To attain the above object, in a semiconductor integrated circuit of the present invention, for example, external terminals of a plurality of chips formed on a wafer are connected by means of wirings in an isolation region of the chips or through an exclusive wiring layer on the wafer, and the connection of the wirings to the inside of the chips can be cut electrically.

With this arrangement, when test data is input or a test result is output from a test signal wiring led out to a wafer peripheral part for the plurality of chips formed on the wafer, the plurality of chips on the wafer can be tested simultaneously with the use of the terminals of which number is less than that of the conventional one. When the connection to the inside of the chips is cut electrically with the use of a fuse or the like after sorting out non-defective chips, electric influence on the chips by noise and degradation caused due to external exposure at the cut faces of the test signal wirings can be prevented. Further, when the circuit for testing the plurality of chips is formed in a region on the wafer where any chip cannot be formed, such as a scribe line or the wafer peripheral part, the test circuit can be formed with no influence involved on the number of chips to be formed. In the case where the test circuit is increased in scale too much to be formed across the scribe line or in the wafer peripheral part, the test circuit is formed in a specific chip formation region or an exclusive test circuit region, enabling test to be performed on the plurality of chips.

In one aspect of the present invention, for testing a chip including a test circuit formed on a wafer, an additional test circuit different from the aforesaid test circuit is formed on a wafer, and the additional test circuit and a chip of which size is smaller than the aforesaid chip are formed only in a specific chip region. Alternatively, a test circuit for testing a chip excluding a test circuit formed on a wafer is formed on the wafer, and the test circuit and a chip of which size is smaller than the aforesaid chip are formed only in a specific chip region. In this way, when the test circuit capable of being shared within the wafer is arranged outside the chip, not inside the chip, and a wiring is connected to each chip, all the chips can be tested by a single test circuit. This arrangement reduces the chip area by the area of the test circuit, leading to reduction in chip cost. Since the test circuit is very small in scale in general, a chip having another function can be arranged in the rest of the specific chip region. This minimizes a wasted wafer area and attains a wafer with the number of chips on the wafer prevented from being reduced as far as possible.

In another aspect of the present invention, a test contact window and a bump are formed in each chip formed on a wafer. This enables signal connection of each chip formed on the wafer by an external device after wafer formation, which means that the test can be performed on the chips at one time.

According to the above aspects, when the test circuit capable of being shared within the wafer is arranged outside the chip, not inside the chip, and the wiring is connected to each chip, the single test circuit can test all the chips, reducing the chip cost. Further, this enables control on the chips at one time, enabling the test to be performed in parallel to reduce the test cost.

In another semiconductor integrated circuit of the present invention, an auxiliary test device and a wiring group for sharing test circuits of a plurality of chips are formed on a wafer. In the case where a test circuit of a to-be-tested chip is out of order, a desired test is performed with the use of a test circuit of a non-target chip, eliminating chip failure caused due to a defective test circuit to improve the chip yield.

Referring to a semiconductor integrated circuit according to one embodiment of the present invention, an external test circuit and test input/output signal group repeater blocks for relaying test input/output signal wiring groups between a plurality of chips are formed on a wafer. Repeater buffers or pipeline flip-flops in the repeater blocks formed on the wafer suppress attenuation in signal level of the test input/output signal wiring groups between the external test circuit and the plurality of to-be-tested chips or suppress generation of high-frequency set up error. Further, the external test circuit can perform a low frequency or high frequency test on a plurality of to-be-tested chips on the wafer.

Another semiconductor integrated circuit according to the present invention includes, on a wafer, a test circuit in which a memory is built and a test control signal output from the test circuit, wherein the test control signal is connected to the same test control terminals of all the chips on the wafer. This enables the test to be performed on all the chips simultaneously, or one by one, or on an arbitrary number of chips designed at the stage of chip design simultaneously. Hence, an arbitrary number of chips on the wafer can be tested simultaneously, so that reduction in test time, peak power consumption, and the like are contemplated at the same time at a high level.

In still another semiconductor integrated circuit according to the present invention, an external test circuit and test input/output signal group repeater blocks for relaying test input/output signal wiring groups between a plurality of chips are formed on a final test board or a burn-in board. Repeater buffer or pipeline flip-flops in the repeater blocks formed on the final test board or the burn-in board suppress attenuation in signal level of the test input/output signal wiring groups between the external test circuit and a plurality to-be-tested chips or suppress generation of high-frequency set up error. Further, a low frequency or high frequency test on the plurality of to-be-tested chips can be achieved by the external test circuit on the final test board or the burn-in board.

### BRIEF DESCRIPTION OF THE DRAWINGS

FIG. 1 is a plan view of a wafer in which a test signal wiring group is formed along a scribe line in a semiconductor integrated circuit according to one embodiment of the present invention.

FIG. 2 is a connection diagram of adjacent chips of the semiconductor integrated circuit according to one embodiment of the present invention.

FIG. 3 is a plan view of a wafer in which a test signal wiring group is formed in an exclusive wiring layer in a semiconductor integrated circuit according to one embodiment of the present invention.

FIG. 4 is a sectional view of conventional chips and a scribe line.

FIG. 5 is a sectional view of chips and a scribe line in one embodiment of the present invention.

FIG. 6 is a sectional view of a scribe line under which a dummy wiring is formed in one embodiment of the present invention.

FIG. 7 is a plan view showing a state in which a test circuit is formed across a scribe line in one embodiment of the present invention.

FIG. 8 is a plan view showing a state in which a test circuit is formed in an exclusive test circuit region in one embodiment of the present invention.

FIG. 9 is a plan view showing a state in which a test circuit is formed in a specific chip formation region in one embodiment of the present invention.

FIG. 10 is a plan view showing a state in which a test circuit is formed in a region of a wafer peripheral part in which any chip cannot be formed.

FIG. 11 is a view showing a configuration in which some of test circuit functions is formed in an adjacent chip region for testing a comparatively small number of chips.

FIG. 12 is a view showing a configuration in which a final test is performed after packaging.

FIG. 13 is a view showing a configuration in which some of test circuit functions is formed in an adjacent chip region for testing chips.

FIG. 14 is a view showing a configuration in which all test circuit functions are formed in an adjacent chip region for testing a comparatively small number of chips.

FIG. 15 is a view showing a configuration in which the final test is performed after packaging.

FIG. 16 is a view showing a configuration in which all test circuit functions are formed in an adjacent chip region for testing chips.

FIG. 17 is a conceptual diagram showing a circuit configuration which share test circuits.

FIG. 18 is a conceptual diagram showing a circuit configuration of a chip including the test circuit in FIG. 17 and a test control circuit.

FIG. 19 indicates one example of a truth table for the test control circuit in FIG. 18.

FIG. 20 is a view showing a configuration in which a minimal pad is provided on each chip.

FIG. 21 is a view showing an arrangement of conventional scan chains.

FIG. 22 is a view showing an arrangement of compressed scan chains.

FIG. 23 is a view showing a connection relationship between test circuits and compressed scan chains.

FIG. 24 is a conceptual illustration showing a circuit configuration of an external test circuit provided on a wafer, a final test board, or a burn-in board and repeater block groups between the external test circuit and to-be-tested chips.

FIG. 25 is a conceptual illustration of the repeater block in FIG. 24.

FIG. 26 indicates one example of a truth table for a control circuit of the external test circuit in FIG. 24.

FIG. 27 is an illustration showing an arrangement in which a minimal pad provided on a chip is connected by an external device.

FIG. 28 is a view of a configuration for testing all chips on a wafer simultaneously.

FIG. 29 is a view of a configuration for testing chips on a wafer one by one.

FIG. 30 is view of a configuration for testing the chips on a wafer in batches.

FIG. 31 is a view showing a conventional burn-in test method.

### DESCRIPTION OF THE PREFERRED EMBODIMENTS

Embodiments of the present invention will be described below with reference to the accompanying drawings.

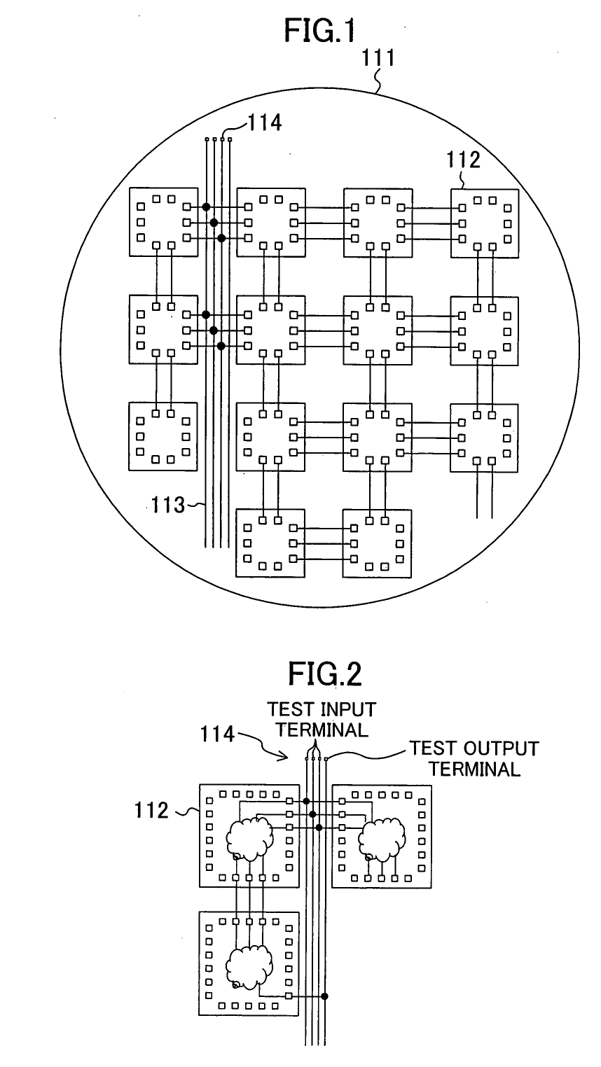

FIG. 1 is a plan view of a wafer of a semiconductor integrated circuit in one embodiment of the present invention. Wirings, which are led out from test terminals of a plurality of chips 112 formed on a semiconductor wafer 111 to the outside of the chips, are all connected to the wafer 111. A test signal wiring group 113, which is formed along a scribe line, is connected to a test terminal group 114 provided in the peripheral part of the wafer 111.

FIG. 2 shows a connection of one 112 of the chips to other adjacent chips. Test input terminals (for example, a clock input terminal, a scan enable input terminal, a scan-in terminal) in the test terminal group 114 are connected to test input terminals of a plurality of chips 112. Test output terminals (for example, a clock output terminal, a scan enable output terminal, a scan-out terminal) of the chip 112 are connected to respective test input terminals of an adjacent chip. The input terminals and the output terminals having the same function are connected to each other. For example, the clock output terminal of the chip 112 is connected to the clock input terminal of the other adjacent chip. A test output terminal (for example, a scan-out terminal) of the adjacent chip is connected to a test output terminal (for example, a scan-out terminal) in the test terminal group 114 through the test signal wiring group 113. Specifically, the circuit configuration is such that test signals are input to the plurality of chips 112 concurrently from the test input terminals in the test terminal group 114 provided at the wafer peripheral part and the plurality of chips 112 are connected in series to propagate the test signal.

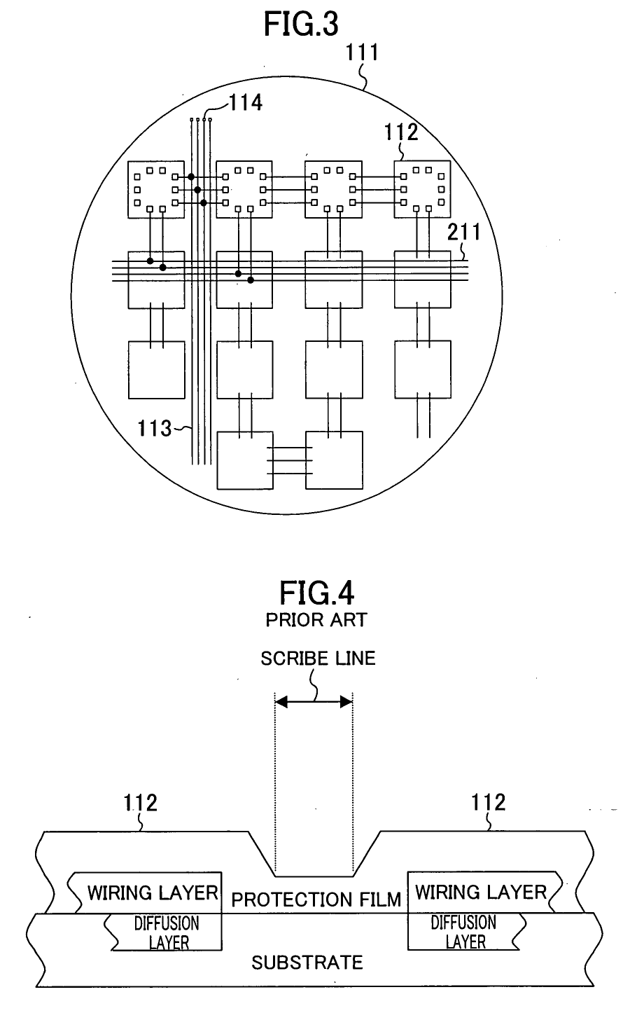

FIG. 3 is a plan view showing a wafer of a semiconductor integrated circuit in another embodiment of the present invention. Wirings, which are led out from test terminals of a plurality of chips 112 formed on a semiconductor wafer 111 to the outside of the chips, are all connected to the wafer 111, and a test signal wiring group 211 formed in an exclusive wiring layer is connected to the test terminal group 114 provided at the peripheral part of the wafer 111. The test signal wiring group 211 is formed in the exclusive wiring layer, and accordingly, may be connected to another chip adjacent to the chip 112 or to another remote chip.

Electrical cutting between the inter-chip wiring and intra-chip wiring for testing will be described with reference to FIG. 4 and FIG. 5.

FIG. 4 is a sectional view of conventional chips and a scribe line. The chips 112 are formed of a plurality of diffusion layers and wiring layers, and a part of each chip other than a bonding pad is covered with a protection film so as to be isolated. Along the scribe line serving as an isolation region of the chips, only the protection film is formed to form a step.

FIG. 5 is a section showing chips and a scribe line in one embodiment of the present invention. While the chips 112 are formed of a plurality of diffusion layers and wiring layers, an inter-chip wiring 321 for testing connected to a test terminal extends over the scribe line so as to be connected to a test terminal of another chip with a fuse 322 interposed.

When the chips 112 are cut and separated along the scribe line, the inter-chip wirings 321 are exposed from the chips at the cut faces of the chips, lowering the reliability of the chip operation. When influence from the outside of the chips is shut out by the fuses 322, however, electric influence on the inside of the chips is prevented, contemplating a stable chip operation.

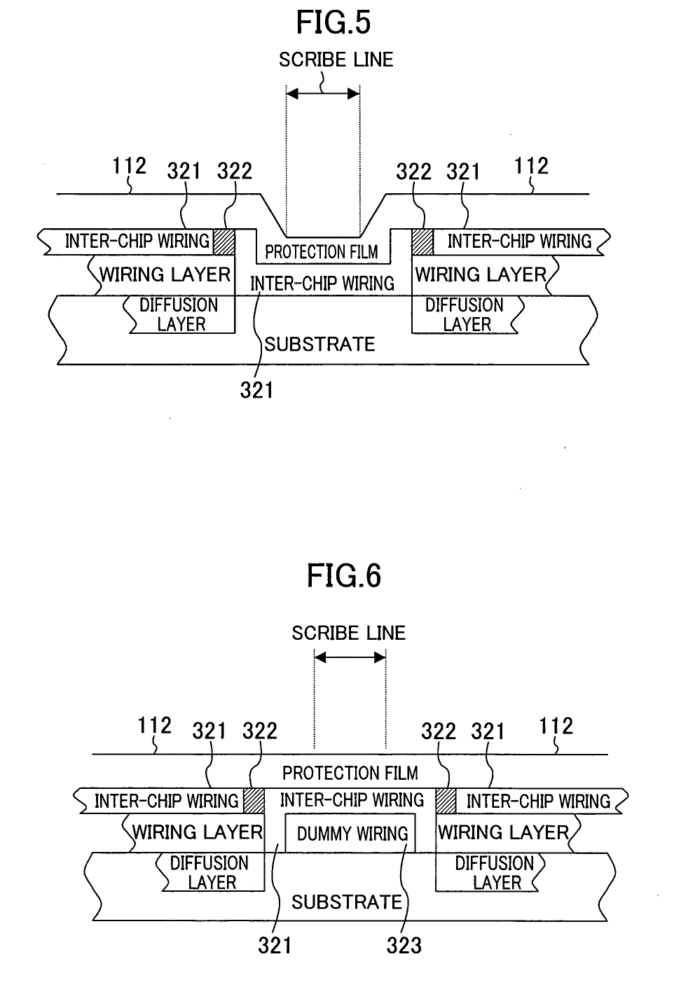

FIG. 6 is a view showing a state in which a dummy wiring 323 is formed below the inter-chip wiring 321 along the scribe line. The dummy wiring 323 avoids an increase in wiring resistance, which is caused due to the presence of the step of a wiring at a scribe line, enabling a high-speed test.

Description will be given next to a circuit for testing a plurality of chips formed on a wafer in one embodiment of the present invention.

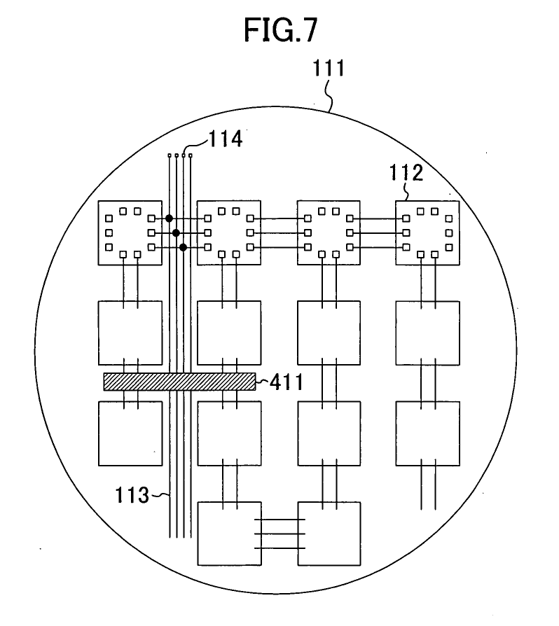

FIG. 7 shows a state in which a test circuit 411 is formed across the scribe line in the wafer 111. The wirings, which are led from the test terminals of the plurality of chips 112 formed on the wafer 111 to the outside of the chips, are all connected to the wafer 111, and the test signal wiring group 113 formed along the scribe line is connected to a test circuit 411 formed across the same scribe line and is led out to the test terminal group 114 provided at the peripheral part of the wafer 111.

Conventionally, a wafer includes a plurality of chips, in each of which a test circuit is built, and a test is performed on the chips one by one. When the chips are the same, the test circuits thereof are the same. Accordingly, concurrent setting to a test mode with the use of the test circuit 411 enables a test to be performed.

A bonding pad may be provided in the test circuit 411 without providing the test terminal group 114. The test signal wiring group 113 may be formed in the exclusive wiring layer on the wafer.

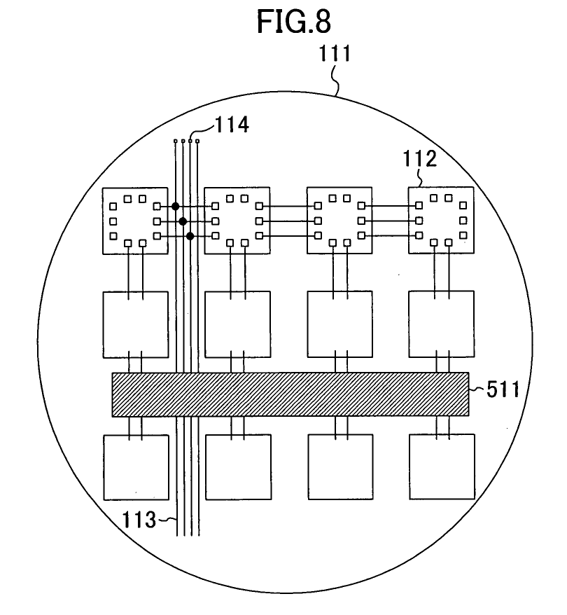

FIG. 8 shows a state in which a test circuit 511 is formed in an exclusive test circuit region. The wirings, which are led from the test terminals of the plurality of chips 112 formed on the wafer 111 to the outside of the chips, are all connected to the wafer 111, and the test signal wiring group 113 formed along the scribe line is connected to the test circuit 511 formed in the exclusive test circuit region and led out to the test terminal group 114 provided at the peripheral part of the wafer 111.

Formation of the test circuit 511 in the exclusive test circuit region on the wafer can address complication and an increase in scale of the test circuit, which is accompanied by an increase in scale of the chips.

A bonding pad may be provided in the test circuit 511 or the exclusive test circuit region without providing the test terminal group 114. The test signal wiring group 113 may be formed in the exclusive wiring layer on the wafer.

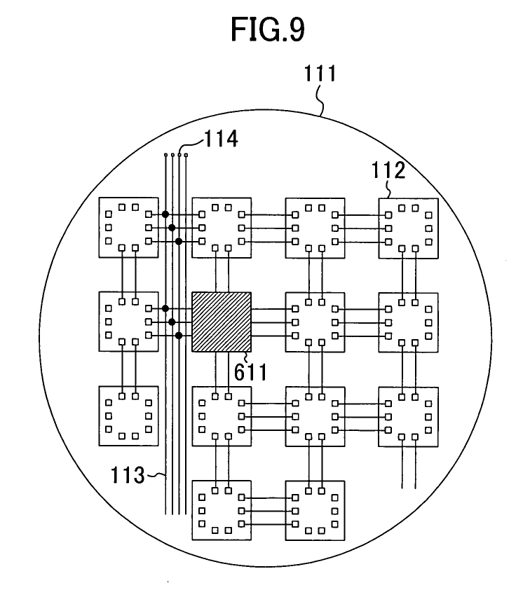

FIG. 9 shows a state in which a test circuit 611 is formed in a specific chip formation region. The wirings, which are led from the test terminals of the plurality of chips 112 formed on the wafer 111 to the outside of the chips, are all connected to the wafer 111, and the test signal wiring group 113 formed along the scribe line is connected to the test circuit 611 formed in the specific chip formation region and is led to the test terminal group 114 provided at the peripheral part of the wafer 111. The number of specific chip formation regions may be plural.

It is noted that a bonding pad may be provided in the test circuit 611 or the chip formation region without providing the test terminal group 114. The test signal wiring group 113 may be formed in the exclusive wiring layer on the wafer.

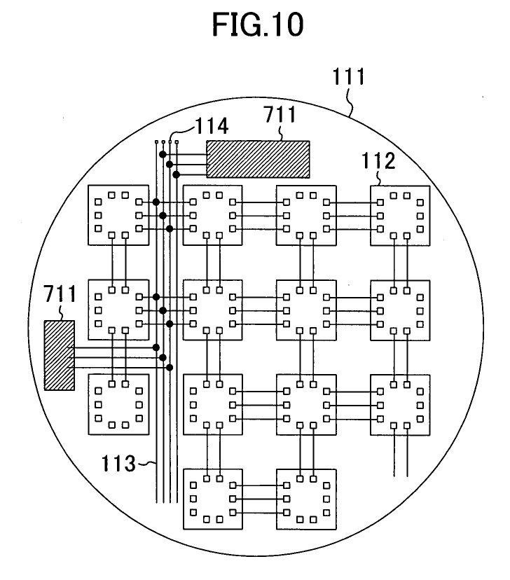

FIG. 10 shows a state in which test circuits 711 are formed in a region of the peripheral part of the wafer in which any chip cannot be formed. The wirings, which are led from the test terminals of the plurality of chips 112 formed on the wafer 111 to the outside of the chips, are all connected to the wafer 111, and the test signal wiring group 113 formed along the scribe line is connected to the test circuits 711 formed in the region of the wafer peripheral part and is led to the test terminal group 114 provided at the peripheral part of the wafer 111.

Bonding pads may be provided in the regions where the test circuits 711 are formed without providing the test terminal group 114. The test signal wiring group 113 may be formed in the exclusive wiring layer on the wafer.

Referring to chips on a wafer, a test circuit is built in each chip on the wafer for checking whether or not the corresponding chip has desired function and performance (built-in test), specifically, whether or not transistors in the corresponding chip operate normally, whether or not they transmit signals at a predetermined speed, or the like. In general, the same test circuit is built in each of the chips on the wafer so that the same test is performed on all the chips. The test circuit has an exclusive function, such as a function of testing built-in of a logic gate (scan test), a function of testing built-in of a built-in memory (memory BIST), or the like. Accordingly, test circuits each having an exclusive function are built in each chip.

In general, multiple memories are built in a chip, and multiple memory BIST (MBIST) circuits for testing the built-in memories are also built therein correspondingly, which increases the area for the MBIST function occupying the chip. To tackling this problem, in the present invention, the memory BIST functions are arranged outside the chip.

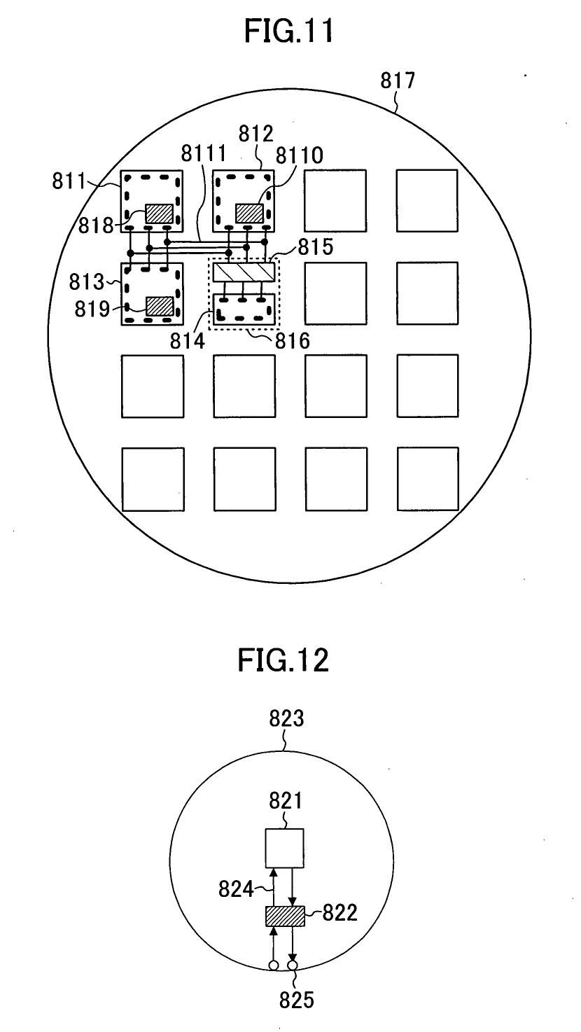

In the embodiment shown in FIG. 11, chips 811, 812, 813 on a wafer 817 have the same function, and only scan test circuits 818, 8110, 819 are built therein, respectively, with no MBIST circuit built in the chips. An MBIST circuit is formed in a chip region 816 adjacent to the chips 811, 812, 813. In general, the chip region 816 has the same size as the chips 811, 812, 813, and accordingly, a chip 814 in this region is smaller in size than the chips 811, 812, 813 and has a function different therefrom. The MBIST circuit 815 is arranged in the rest of the chip region 816 other than the chip 814. When the MBIST circuit 815 is connected to the chips 811, 812, 813, 814 through wirings 8111 along the scribe line or on the chips by the technique described with reference to FIG. 1 through to FIG. 6, the built-in memories in the chips can be tested. A test is performed in such a manner that the MBIST circuit 815 outputs the same signals at one time to the chips 811, 812, 813 and takes therein test responses from the built-in memories by the technique under-mentioned with reference to FIG. 26. The MBIST circuit 815 can test the built-in memories of the chip 814 similarly. With this arrangement, the built-in memories of the three chips can be tested substantially simultaneously, contemplating reduction in test time. Further, the MBIST circuit 815 is formed outside the chips, reducing the chip area to lead to cost reduction.

FIG. 12 shows an embodiment of a test after a chip is packaged. A final-stage semiconductor integrated circuit as a chip separated from a wafer and packaged is inserted into a socket 821 mounted on a test board 823. A test circuit 822 separated from the wafer similarly is mounted on the test board 823. The test circuit 822 is connected to the socket 821 through a wiring 824 on the test board 823, and test data is applied through an external terminal 825 from an external tester. When the present embodiment is employed, arrangement of the MBIST circuit on the test board after a wafer-level test is completed enables a package-level test.

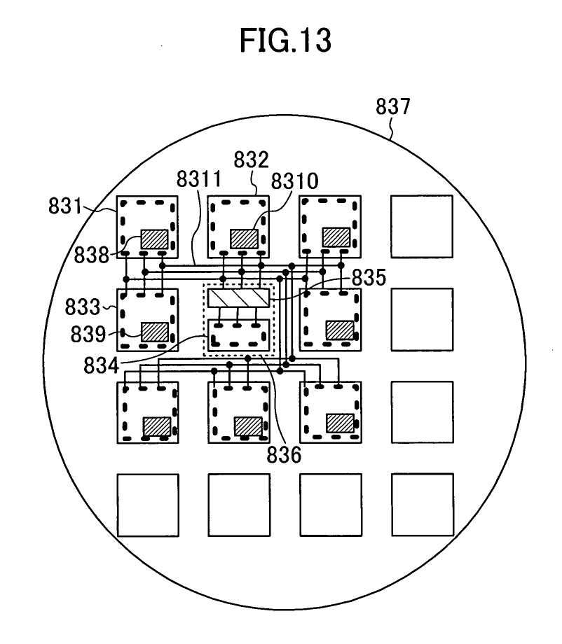

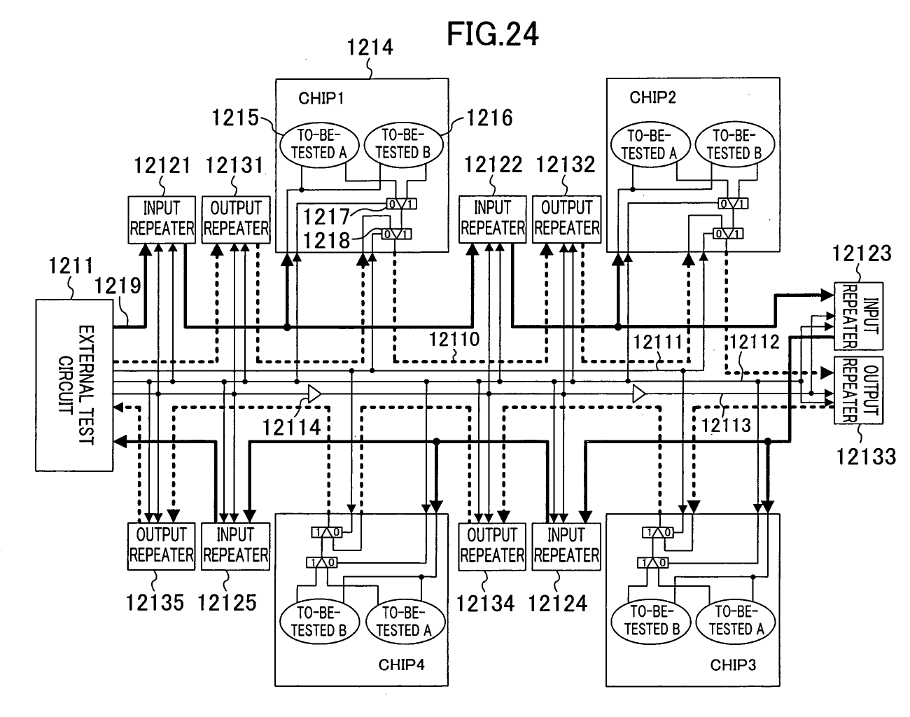

FIG. 11 refers to the case with four chips. In contrast, FIG. 13 shows a state in which a larger number of chips are tested similarly. Chips having the same function as a chip 831 are arranged so as to surround a chip region 836. These chips must be tested by a MBIST circuit 835. As the number of chips is increased, delay of a signal from the MBIST circuit 835 and each inclination of rise and fall of the signal increase, resulting in an inaccurate test performed. To tackling these problems, increases in signal delay and in each inclination of signal rise and fall are prevented by the technique under-mentioned with reference to FIG. 24, thereby achieving an accurate test.

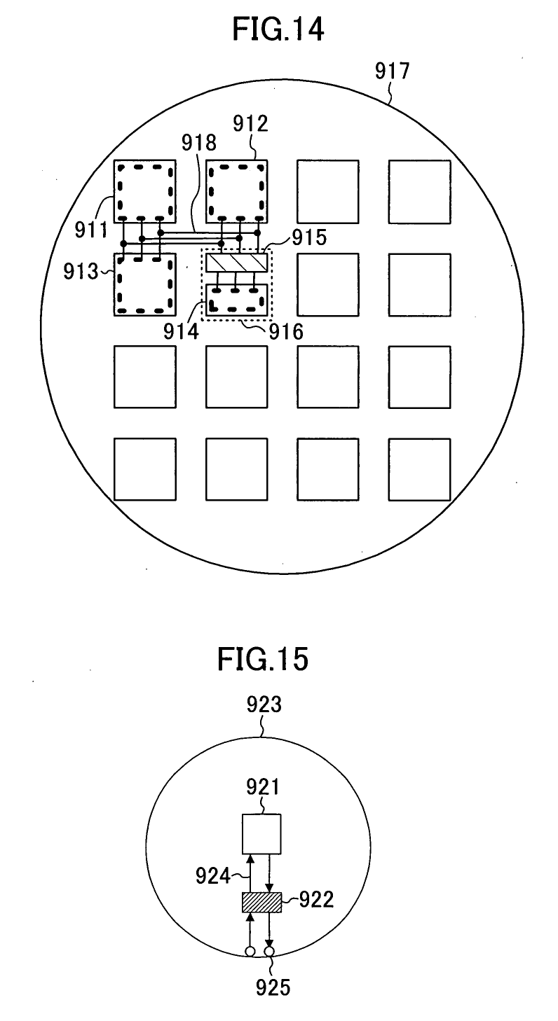

In an embodiment shown in FIG. 14, chips 911, 912, 913 on a wafer 917 have the same function and include no test circuit. An MBIST circuit and a scan test circuit are arranged as a test circuit 915 in a chip region 916 adjacent to the chips 911, 912, 913. In general, the chip region 916 has the same size as the chips 912, 912, 913, and accordingly, a chip 914 in this region is smaller in size than the chips 911, 912, 913 and has a function different therefrom. The test circuit 915 is arranged in the rest of the chip region 916 other than the chip 914. When the test circuit 915 is connected to the chips 911, 912, 913, 914 through wirings 918 along the scribe line or on the chips by the technique descried with reference to FIG. 1 through to FIG. 6, these chips can be tested. A test is performed in such a manner that the test circuit 915 outputs the same signals at one time to the chips 911, 912, 913 and takes therein test responses from the chips by the technique under-mentioned with reference to FIG. 24. The test circuit 915 can test the chip 914 similarly. With the above arrangement, the three chips can be tested substantially simultaneously, reducing the test time. Further, with all the test circuits provided outside the chips, further reduction in chip area is achieved when compared with the case in FIG. 11, leading to cost reduction.

FIG. 15 shows an embodiment of a test after a chip is packaged. A final-stage semiconductor integrated circuit as a chip separated from a wafer and packaged is inserted into a socket 921 mounted on a test board 923. A test circuit 922 separated from the wafer similarly is mounted on the test board 923. The test circuit 922 is connected to the socket 921 through a wiring 924 on the test board 923, and test data is applied through an external terminal 925 from an external tester. When the present embodiment is employed, arrangement of the test circuit on the test board after a wafer-level test is completed enables a package-level test.

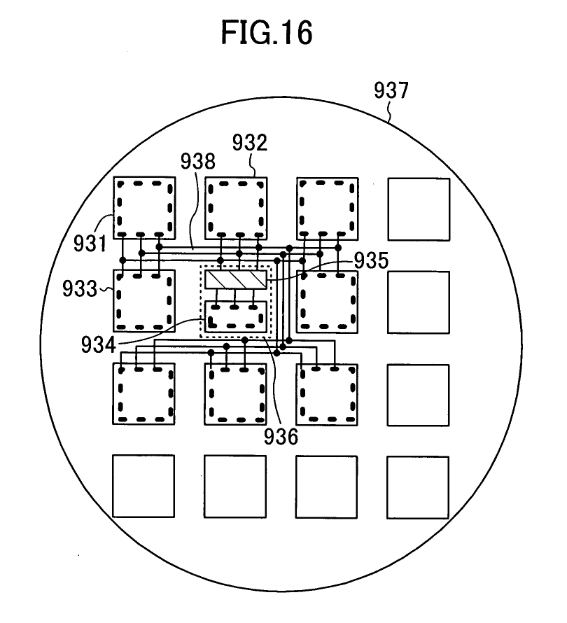

FIG. 14 refers to the case with four chips. In contrast, FIG. 16 shows a state in which a larger number of chips are tested similarly. Chips having the same function as a chip 931 are arranged so as to surround a chip region 936. These chips must be tested by a test circuit 935. As the number of chips is increased, delay of a signal from the test circuit 935 and each inclination of rise and fall of the signal increase, resulting in an inaccurate test performed. To tackling these problems, increases in signal delay and in each inclination of signal rise and fall are prevented by the technique under-mentioned with reference to FIG. 24, thereby achieving an accurate test.

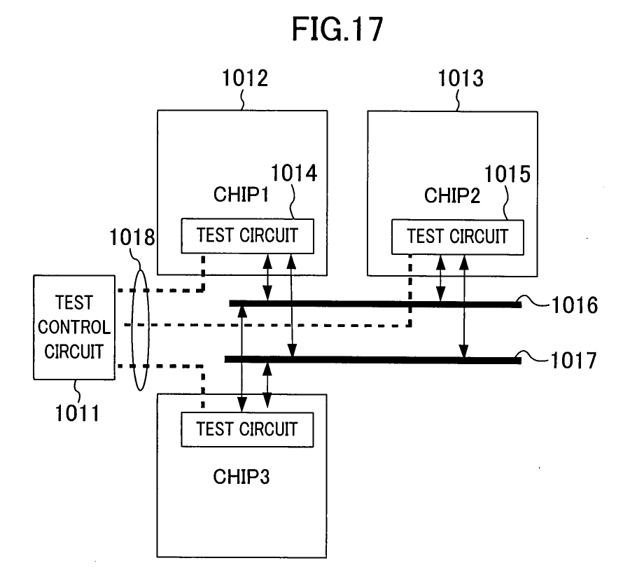

FIG. 17 shows one embodiment of a circuit configuration where a to-be-tested chip and a non-target chip share test circuits. This configuration improves a problem in which a to-be-tested chip cannot be tested because a test circuit of the to-be-tested chip is out of order. In FIG. 17, reference numeral 1011 denotes a test control circuit, 1012 denotes a to-be-tested chip, 1013 denotes a non-target chip, 1014 denotes a test circuit of the to-be-tested chip 1012 that is out of order, 1015 denotes a test circuit of the non-target chip 1013, 1016 denotes a test circuit input wiring group, 1017 denotes a test circuit output wiring group, and 1018 denotes a control wiring group between the test control circuit and the chips.

An operation of the configuration shown in FIG. 17 will be described. First, in the case where the test circuit 1014 is out of order for performing a test on the to-be-tested chip 1012, information that it is out of order is transmitted to the test control circuit 1011 through the wiring group 1018. Upon receipt of this information, the test control circuit 1011 transmits information for activating the test circuit 1015 of the non-target chip 1013, which has an equivalent function to that of the test circuit 1014, through the wiring group 1018. Under this state, the to-be-tested chip 1012 is tested by the test circuit 1015 of the non-target chip 1013 through the wiring groups 1016, 1017.

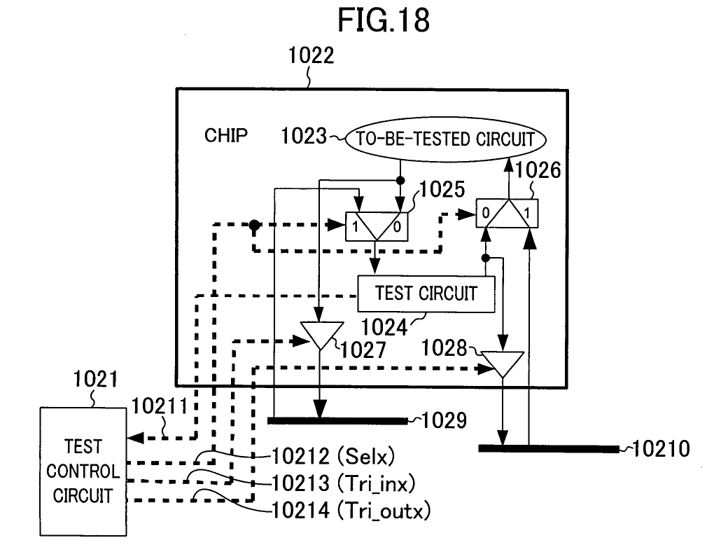

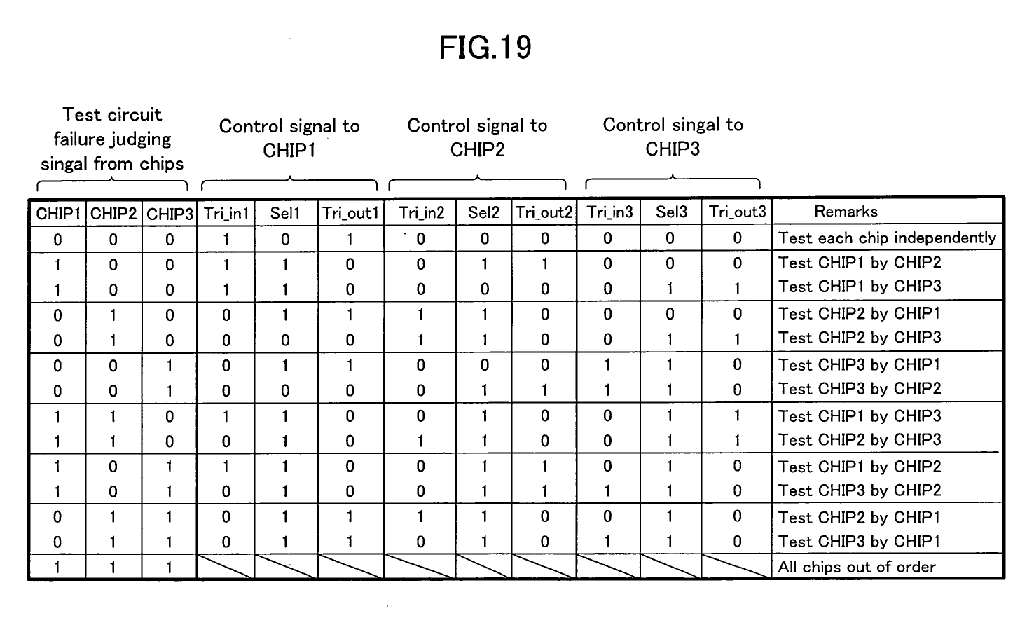

The circuit operation will be described below further in detail with reference to FIG. 18 and FIG. 19. FIG. 18 shows one example of a circuit configuration of a chip including the test circuit and a test control circuit described above. FIG. 19 is a truth table for the test control circuit in FIG. 18.

In FIG. 18, reference numeral 1021 denotes a test control circuit, 1022 denotes a to-be-tested chip, 1023 denotes a to-be-tested circuit, 1024 denotes a test circuit, 1025 denotes an input selector to the test circuit 1024, 1026 denotes an output selector from the test circuit 1024, 1027 denotes a tri-state buffer connected to a test circuit input wiring group, 1028 denotes a tri-state buffer connected to a test circuit output wiring group, 1029 denotes the test circuit input wiring group, 10210 denotes the test circuit output wiring group, 10211 denotes a test circuit failure judging wiring, 10212 denotes a test circuit selector wiring (Selx), 10213 denotes a test circuit input tri-state enable wiring (Tri_inx), and 10214 denotes a test circuit output tri-state enable wiring (Tri_outx).

In a state where the test circuit 1024 of the to-be-tested chip 1022 is not out of order, a low-level signal is transmitted to the test control circuit 1021 through the control signal wiring 10211. In contrast, in a state where the test circuit 1024 is out of order, a high-level signal is transmitted to the test control circuit 1021 through the control signal wiring 10211. The test control circuit 1021 controls, on the basis of the truth table in FIG. 19, the test circuit 1024 of another chip to allow it to perform a test on the chip of which test circuit 1024 is out of order. As one example, the case in FIG. 17 will be described where the test circuit 1014 of CHIP1 is out of order while the test circuit 1015 of CHIP2 is not out of order. The level of the test circuit failure judging wiring 10211 of CHIP1 is HIGH while that of the test circuit failure judging wiring 10211 of CHIP2 is LOW. On the basis of the corresponding line in the remark column of the truth table in FIG. 19, namely, “test CHIP1 by CHIP2”, the test control circuit 1021 transmits control signals of Tri_in1=1, Sel1=1, and Tri_out1=0 to CHIP1 and control signals of Tri_in2=0, Sel2=1, and Tri_out2=1 to CHIP2 through the test circuit input tri-state enable wiring 10213, the test circuit selector wiring 10212, and the test circuit output tri-state enable wiring 10214, respectively. Signal transmission from the to-be-tested circuit 1023 of CHIP1 to the test circuit 1024 of CHIP2 in this case is as follows. Namely, the output signal group of the to-be-tested circuit 1023 of CHIP1 is propagated to the test circuit input wiring group 1029 through the tri-state buffer 1027 (Tri_in1=1) connected to the test circuit input wiring group and then is connected to the test circuit 1024 of CHIP2 through the input selector 1025 (Sel2=1) of CHIP2 to the test circuit. Similarly, signal transmission from the test circuit 1024 of CHIP2 to the to-be-tested circuit 1023 of CHIP1 is as follows. Namely, the output signal group of the test circuit 1024 of CHIP2 is propagated to the test circuit output wiring group 10210 through the tri-state buffer 1028 (Tri_out2=1) connected to the test circuit output wiring group and then is connected to the to-be-tested circuit 1023 of CHIP3 through the output selector 1026 (Sel1=1) of CHIP1 from the test circuit 1024.

As described above, the to-be-tested chip and the non-target chip share the test circuits in the present configuration, so that a test can be performed by using a test circuit of a non-target chip when a test circuit of a to-be-tested chip is out of order.

The test circuits, each of which has an exclusive function for a scan test, a memory BIST, or the like, are built in a chip. A recent increase in scale of SoC (System on Chip) remarkably increases the amount of test pattern for, especially, a scan test, and, a compressed scan test catches attention accordingly as a method for reducing the amount of test pattern.

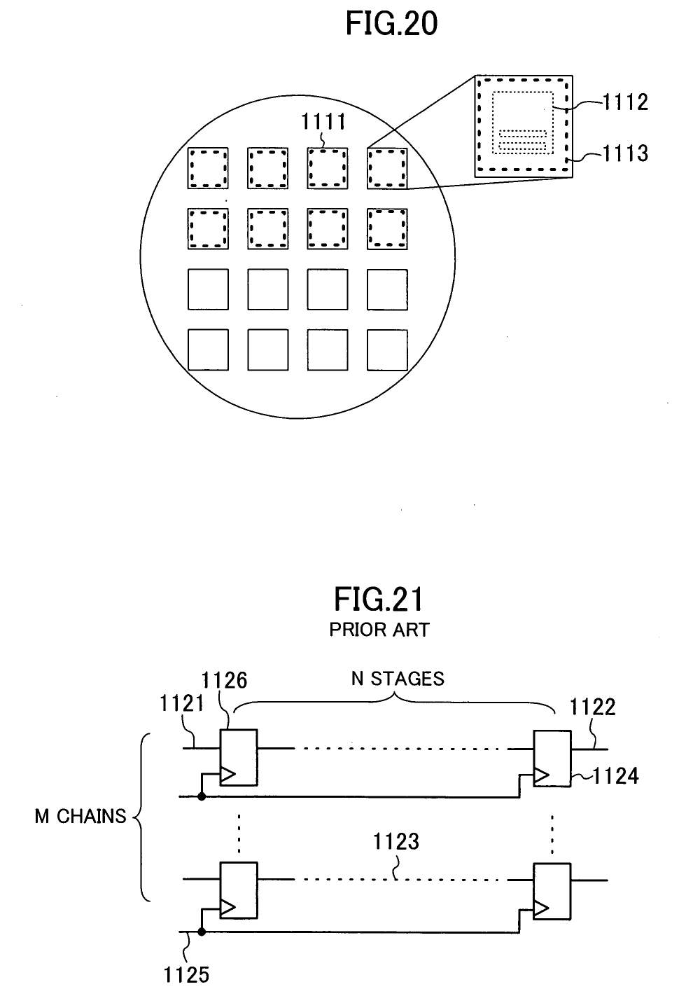

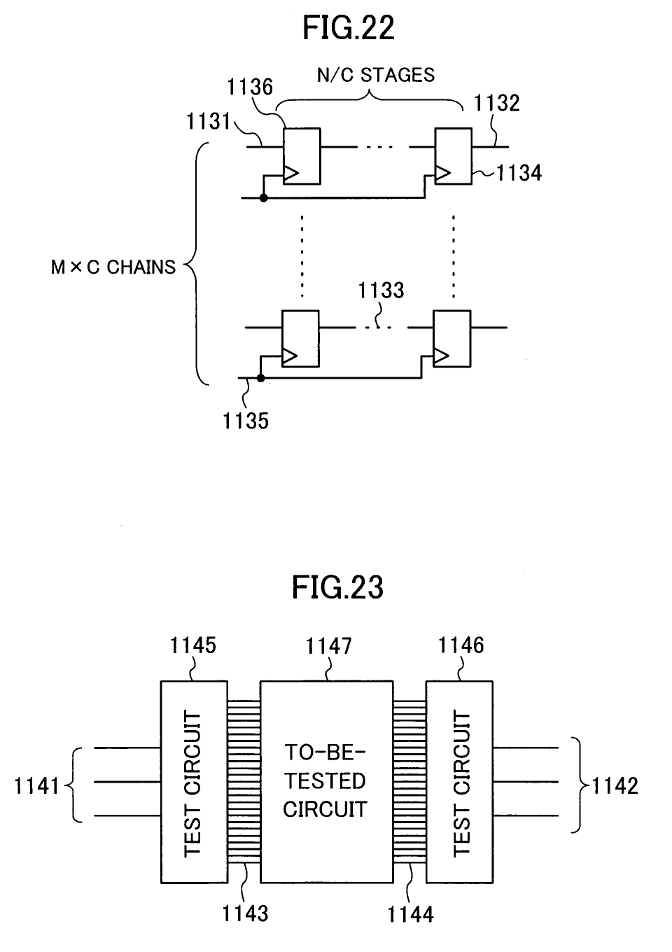

Prior to description of one embodiment of the present invention with reference to FIG. 20, difference between the compressed scan test and a conventional scan test will be described with reference to FIG. 21 and FIG. 22.

FIG. 21 shows a structure of scan chains in a logic circuit on which a conventional scan test is to be performed. A test pattern input from a scan-in 1121 as an exclusive test terminal reaches a data terminal of a scan flip-flop 1126 at the initial stage. When scan clocks 1125 are applied then, the values of the scan flip-flops shift in accordance with the time cycle of the scan clocks 1125. When the scan clocks 1125 of which number is equal to the number N of stages, that is, the number of flip-flops of each scan chain are input, the value thereof reaches a scan flip-flop 1124 at the final stage and is output from an exclusive test scan-out 1122. Conventionally, there are formed M scan chains 1123 under this connection. Usually, the amount of the test pattern is estimated roughly by multiplying the number M of the scan chains by the number of stages N of each scan chain, and accordingly, is expressed by N×M steps.

A structure of the compressed scan test will be described next with reference to FIG. 22. The structure itself is equivalent to that of the conventional scan design. Namely, a test pattern input from a scan-in 1131 as an exclusive test terminal reaches a data terminal of a scan flip-flop 1136 at the initial stage. When scan clocks 1135 are applied then, the value of the scan flip-flops shifts in accordance with the time cycle of the scan clocks 1135. When the scan clocks 1135 of which number is equal to N/C stages, that is, the number of the flip-flops of each scan chain are input, the value thereof reaches a scan flip-flop 1134 at the final stage and is output from an exclusive test scan-out 1132. Differences from the conventional one are that the number of scan chains under this connection is M×C and that a test circuit for the compressed scan test is added to the outside of the to-be-tested circuit. The added test circuit, which has scan-ins and scan-outs of which numbers are the same as those in the conventional scan test, develops scan-in data therein C times and applies it to the scan-ins 1131 of the to-be-tested circuit. A test device connected outside the semiconductor integrated circuit can perform a test at an amount of scan test pattern which corresponds to the number of the conventional scan-ins, that is, M×N/C stages.

FIG. 23 shows a connection relationship between a to-be-tested circuit and test circuits in the compressed scan test. While the numbers of external scan-ins 1141 and external scan-outs 1142 serving as interfaces with an external tester are the same as those in the conventional scan test, test circuits 1145, 1146 are provided inside the chip as test pattern development/compression circuits and are connected to internal scan chains 1143, 1144 of a to-be-tested circuit 1147, respectively. The number of the internal scan chains inside the chip is several tens times that of the external scan chains. When the number of stages of the internal scan chains is set to one several tenth, the amount of the test pattern can be reduced to one several tenth. The compressed test pattern is applied inside the chip from the external scan-ins 1141 of which number is the same as that of the conventional one, is developed to several tens times at the test circuit 1145, and then, is applied to the scan chains of the to-be-tested circuit 1147 of which number is several ten times. The test result is compressed in the test circuit 1146 and is output to the external scan-outs 1142 of which number is equal to the conventional one.

One embodiment of the present invention will be described with reference to FIG. 20. In order to performing the above described compressed scan test, a chip 1111 includes scan chains of which number is several tens times that in the conventional scan design. Though the number of the external input/output terminals 1113 for the scan test is equal to that in the conventional scan design, the internal scan chains for input/output amounts to several thousands in total according to SoC in some cases. Input/output to and from the internal scan chains are performed through a pad (minimal pad) 1112 with a bump of several tens microns square rather than an I/O pad. With this arrangement, the connection to the outside of the chip is achieved. Arrangement of the minimal pad at any place on the chip comparatively facilitates the connection to the outside.

FIG. 24 shows one embodiment of a circuit configuration in which a plurality of to-be-tested chips on a wafer, a final test board, or a burn-in board is subjected to a low-frequency or high-frequency test by an external test circuit. In FIG. 24, reference numeral 1211 denotes an external test circuit, 12121 to 12125 each denote a test input signal group repeater block, 12131 to 12135 each denote a test output signal group repeater block, 1214 denotes a to-be-tested chip, 1215 denotes a to-be-tested circuit A, 1216 denotes a to-be-tested circuit B, 1217 denotes a to-be-tested circuit selector macro, 1218 denotes a chip selector macro, 1219 denotes a test input signal wiring group, 12110 denotes a test output signal wiring group, 12111 denotes a chip select signal wiring group (CHIPSEL [3:0]), 12112 denotes a to-be-tested circuit select signal wiring (TESTSEL), 12113 denotes a repeater block clock signal wiring, and 12114 denotes a clock repeater buffer macro.

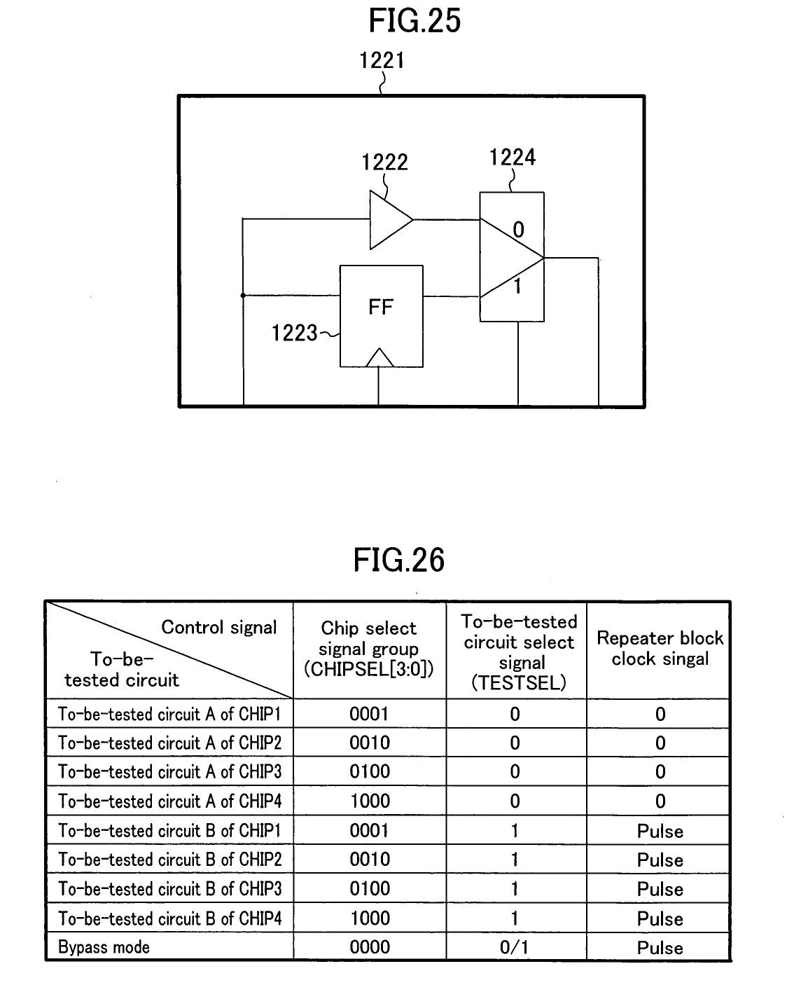

In FIG. 25, reference numeral 1221 denotes a test signal group repeater block, 1222 denotes a repeater buffer macro, 1223 denotes a pipeline flip-flop macro, and 1224 denotes a selector macro. Further, FIG. 26 indicates a truth table for a control circuit operation of an external test circuit.

An operation in FIG. 24, FIG. 25 and FIG. 26 will be described. First, a control circuit of the external test circuit 1211 issues a chip select signal 12111 (CHIPSEL [3:0]), a to-be-tested circuit select signal 12112 (TESTSEL), and a repeater block clock signal 12113 on the basis of the truth table in FIG. 26.

In the case where the to-be-tested circuit A (1215) of CHIP1 is tested at low frequency, the chip select signal CHIPSEL [3:0] is 0001, the to-be-tested circuit select signal TESTSEL is 0, and the repeater block clock signal 12113 is LOW. In this state, the test input signal group 1219 is input to the input repeater block 12121. In the input repeater block 12121, the selector macro 1224 selects an output of the repeater buffer 1222 to amplify the signal level of the input signal group 1219, and then, the input signal group is input to the to-be-tested circuit A (1215) of CHIP1. Subsequently, the output signal group from the to-be-tested circuit A (1215) of CHIP1 is input to the external test circuit 1211 by way of the to-be-tested circuit selector macro 1217 (TESTSEL=0), the chip selector macro 1218 (CHIPSEL [0]=1), the output repeater block 12132, the selector macro (CHIPSEL [1]=0) of CHIP2, the output repeater block 12133, the selector macro (CHIPSEL [2]=0) of CHIP3, the output repeater block 12134, the selector macro (CHIPSEL [3]=0) of CHIP4, and the output repeater block 12135 in this order with the signal level thereof amplified by the respective repeater buffer macros 1222 in the respective repeater blocks 1221.

In the case where the to-be-tested circuit B (1216) of CHIP1 is tested at high frequency, the chip select signal CHIPSEL [3:0] is 0001, the to-be-tested circuit select signal TESTSEL is 1, and the repeater block clock signal 12113 is of a high frequency clock pulse type. Attenuation of the signal level of the high frequency clock pulse signal 12113 is suppressed by the clock repeater buffer macro 12114. In this state, the test input signal group 1219 is input to the input repeater block 12121. In the input repeater block 12121, the selector macro 1224 selects an output of the pipeline flip-flop 1223, to which the repeater block high frequency clock signal 12113 is input, to pipeline the signal level of the input signal group 1219 at high frequency, and then, the signal group is input to the to-be-tested circuit B (1216) of CHIP1. Next, the output signal group from the to-be-tested circuit B (1216) of CHIP1 is input to the external test circuit 1211 by way of the to-be-tested circuit selector macro 1217 (TESTSEL=1), the chip selector macro 1218 (CHIPSEL [0]=1), the output repeater block 12132, the selector macro (CHIPSEL [1]=0) of CHIP2, the output repeater block 12133, the selector macro (CHIPSEL [2]=0) of CHIP3, the output repeater block 12134, the selector macro (CHIPSEL [3]=0) of CHIP4, and output repeater block 12135 in this order with the repeater block high frequency clock signal 12113 in the repeater block 1221 pipelined at high frequency by the input pipeline flip-flop macro 1223.

In the low-frequency test, with no amplification by the repeater buffer macros in the repeater blocks, the signal level of the test signal wiring group is attenuated in the cause of signal transmission from the external test circuit to a repeater block, from the repeater block to a to-be-tested chip, from the to-be-tested chip to another repeater block, from the other repeater block to still another repeater block, and from the still other repeater block to the external test circuit. The present configuration resolves this disadvantage, as described above.

As well, in the high-frequency test, with no pipeline by the flip-flops in the repeater blocks, a set-up timing error is caused, so that the signal level at high frequency of the test signal wiring group cannot be kept in the course of signal transmission from the external test circuit to a repeater block, from the repeater block to a to-be-tested chip, the to-be-tested chip to another repeater block, from the other repeater block to still another repeater block, and from the still other repeater block to the external test circuit. The present configuration resolves this disadvantage.

In the present configuration, the test input or output signals are amplified or pipelined in the repeater blocks of the test input/output signal groups, so that a plurality of to-be-tested chips on a wafer, a final test board, or a burn-in board can be tested at low frequency or high frequency by the external test circuit.

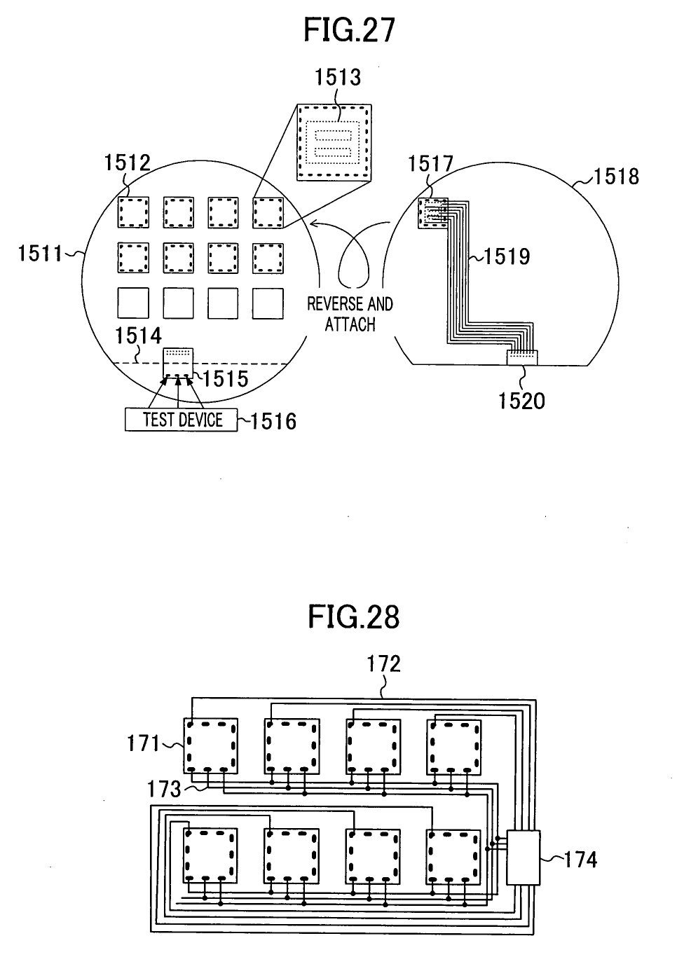

An embodiment shown in FIG. 27 stands on the assumption of the wafer in any of the embodiments shown in FIG. 20 to FIG. 23 and an arrangement of the test circuit(s) shown in any of FIG. 7 to FIG. 10. A wafer 1511 includes chips 1512 and a test circuit 1515 arranged across a scribe line, in a chip region, in a test circuit region, or in the peripheral part of the wafer in which any chip cannot be formed. In each of the chips 1512, there is arranged a pad (minimal pad) 1513 with a bump of several-tens microns square which is connected to a to-be-tested circuit in the corresponding chip. The test circuit 1515 is composed of a compressed test pattern developing circuit, a test result compression circuit, and the like. In the test circuit 1515, since the internal scan chains necessitates a considerable number of signals, a pad (minimal pad) with a bump of several tens microns square is arranged similarly to the chips 1512 and a conventional I/O pad for a test device 1516 is provided in addition. The I/O pad corresponds to the aforementioned external scan-ins and external scan-outs. The test device 1516 actually performs a test by applying a probe or the like to the I/O pad. A wiring device denoted by 1518 includes an interconnect 1519 for connecting the chip 1512 and the pad (minimal pad) with a bump of several tens microns square of the test circuit 1515. When the wiring device 1518 is reversed and attached, the chip 1512 is connected to the test circuit 1515 to allow the test device 1516 to control the chip 1512. Though one chip 1512 corresponds to one test circuit 1515 in the present example, one test circuit can test all of the chips to the maximum.

In an embodiment shown in FIG. 28, test control signals 173 from a test circuit 174 are connected to chips 171 and the like on a wafer. As to the test control signals 173, the same signals are connected to the same terminals of each chip and are each composed of a test pattern for testing the chips 171, a clock, and another control signal. The test circuit 174 is composed of a BIST (Built-In Self Test) circuit or the like and is controlled by an external test device to apply the test pattern, the clock, and the other control signal to the chips. With these signals, all the chips on the wafer can be tested simultaneously. A test result signal 172 for transmitting a test result to the test circuit 174 is connected to a test result output terminal of each chip. Accordingly, when the number of chips 171 is 1000, the number of test result signals 172 is 1000. In the test circuit 174, memory circuits are built for holding the contents of the test result signals 172. The memory circuits correspond to all the chips on the wafer and are set in one-to-one correspondence with the chips. Accordingly, when 1000 chips 171 is formed on the wafer, 1000 memories are provided, each of which is read out to a tester outside the wafer. The test circuit 174 is controlled by an external tester to apply a test pattern to all the chips on the wafer, to allow the memory circuits in the test circuit to hold the test results from the chips, and then to allow the external tester to read out a memory value arbitrarily. This enables a test to be performed on all the chips in parallel, remarkably reducing the test time. In this chip configuration, however, a large number of transistors must be operated simultaneously, involving an increase in power consumption, which may lead to an unstable test. A remedial method for this will be shown below.

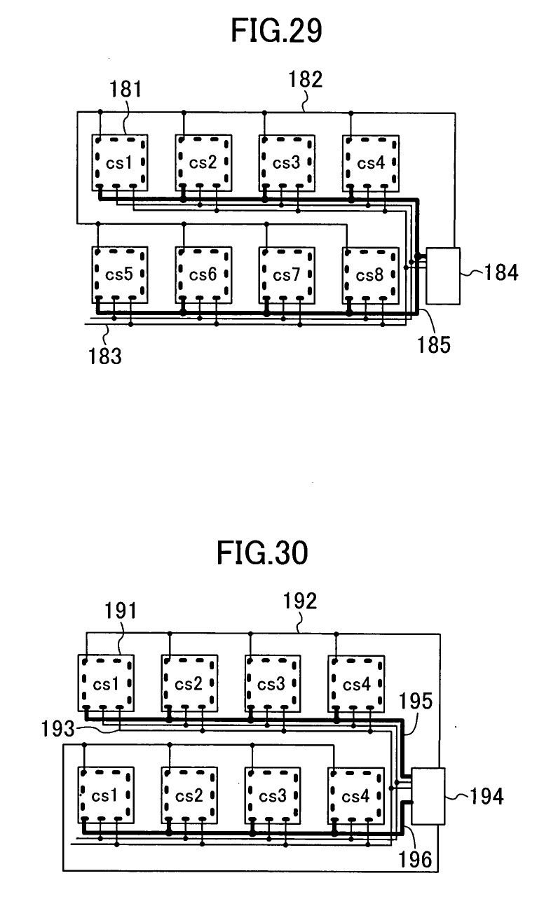

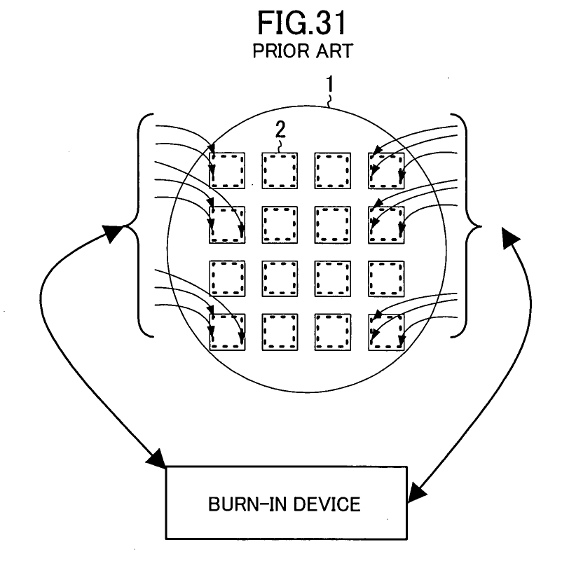

In an embodiment shown in FIG. 29, test control signals 183 from a test circuit 184 are connected to chips 181 and the like on a wafer. The test control signals 183 are connected to all the chips and are composed of a test pattern for testing the chips 181, a clock, and other control signals. Particularly, the other control signals include a chip select signal 185. The chip select signal 185 is a signal for selecting all the chips on the wafer one by one. For selecting any one of 1000 chips, 10-bit chip select signal is necessary, and each of the chips decodes the signal thereinside for identifying signal of its own. With this signal, the test circuit 184 selects any of the chips on the wafer with the use of the chip select signal to perform a test on only the selected chip. The chip select signal is generated in the test circuit 184. Upon receipt of a test start pulse (test on cs1) from an external test device, a counter increments and holds the incremented value until the next test start pulse (test on cs2). Repetition of this operation by times of which number is equal to the number of the chips generates the chip select signal for all the chips. There are provided test result signals 182 for transmitting test results to the test circuit 184, which are connected to the test result output terminals of all the chips, wherein all the test result output signals are bus-connected. Each chip 181 includes a tri-state buffer for outputting a test result to the bus upon receipt of the chip select signal. With this tri-state buffer, the number of the test result output signal wirings on the wafer is limited even if the number of the test result signals for the compressed scan test and the like is multiple. For example, only 100 signal wirings are necessary for 100 test result output terminals. The test circuit 184 is controlled by an external tester to apply a test pattern to all the chips on the wafer and to output a test result from each chip to the external tester, thereby enabling a test to be performed on all the chips one by one. For testing multiple chips at one time, power consumption increases in general to invite an unstable test. In this case, in contrast, though a long time is required for the test, the one-by-one test prevents insufficient power supply in the test. A remedial method for this will be shown below.

In an embodiment shown in FIG. 30, test control signals 193 from a test circuit 194 are connected to chips 191 and the like on a wafer. The test control signals 193 are connected to all the chips and are composed of a test pattern for testing the chips 191, a clock, and other control signals. Particularly, the other control signals include chip select signals 195 and 196. These signals select predetermined chips so that only the selected chips on the wafer selected by the control signal 195 or 196 are tested. In the present embodiment, two chip select signals are provided so that the chips on the wafer can be tested two by two. The chip select signals 195 and 196 from the test circuit 194 are the same and are used for a test on cs1 and cs1, for example, simultaneously. At the next test start pulse, cs2 and cs2 are tested simultaneously. Repetition of this operation results in tests on all the chips on the wafer. There are provided test result signals 192 for transmitting test results to the test circuit 194, which are connected to the test result output terminals of all the chips, wherein all the test result output signals of the chips connected by the same chip select signal are bus-connected. Each chip 191 includes a tri-state buffer for outputting a test result to the bus upon receipt of the chip select signal. The test circuit 194 is controlled by the external tester to apply a test pattern to all the chips on the wafer and to output a test result from each chip to the external tester, thereby enabling a test to be performed on all the chips two by two. For testing multiple chips at one time, power consumption increases in general to invite an unstable test. In this case, in contrast, the two-by-two test prevents insufficient power supply in the test, and the test time is reduced to one half of that of the one-by-one test. As described above, as the number of chips connected to the chip select signal of the same signal wiring is small, the test time is long while the peak power is small. In reverse, as the number of chips connected to the chip select signal of the same signal wiring is large, the test time is short while the peak power is large. It is essential to design a test circuit and a decode circuit in a chip at the stage of chip design with the peak power in testing and power supply capacity of a test device taken into consideration.

As described above, the semiconductor integrated circuit of the present invention is provided with, for example, a wiring along the a scribe line and a fuse for cutting it, so that the same terminals of all or a part of chips on a wafer can be connected, enabling a part or all of test circuits to be shared among the chips. This can reduce the test time and the chip area and is useful for reduction in chip cost.

What is claimed is:

1. A semiconductor integrated circuit, wherein external terminals of a plurality of chips formed on a wafer are connected by means of wirings in an isolation region of the chips, and the connection of the wirings to the inside of the chips is capable of being cut electrically.

2. The semiconductor integrated circuit of claim 1,
wherein a dummy wiring layer is formed under a wiring layer connected in the isolation region of the chips.

3. A semiconductor integrated circuit, wherein a test circuit for testing a plurality of chips formed on a wafer is formed in an isolation region of the chips on the wafer.

4. A semiconductor integrated circuit, wherein a plurality of chips are formed on a wafer, and a test auxiliary device having a function of sharing a test circuit of each of the chips is formed on the wafer so as to perform a test with the use of a test circuit of a non-target chip when a test circuit of a to-be-tested chip is out of order.

5. A semiconductor integrated circuit of claim 3,
wherein a repeater block group composed of repeater buffers between the test circuit and a to-be-tested chip and a control circuit for selecting the to-be-tested chip is provided on the wafer for performing a low-frequency test on the plurality of chips, such as a scan test, a direct memory access test, or the like.

6. The semiconductor integrated circuit of claim 3,
wherein a repeater block group composed of pipeline flip-flops between the test circuit and a to-be-tested chip and a control circuit for selecting the to-be-tested chip are provided on the wafer for performing a high-frequency test on the plurality of chips, such as a logic random pattern test, a memory random pattern test, or the like.

7. The semiconductor integrated circuit of claim 5,
wherein another repeater block group composed of pipeline flip-flops between the test circuit and a to-be-tested chip and a control circuit for selecting the to-be-tested chip are further provided on the wafer for performing a high-frequency test on the plurality of chips, such as a logic random pattern test, a memory random pattern test, or the like.

8. The semiconductor integrated circuit of claim 3,
wherein input and output signals of the test circuit are connected to the plurality of chips in parallel.

9. The semiconductor integrated circuit of claim 3,
wherein input and output signals of the test circuit are connected to the plurality of chips in series.

10. A semiconductor integrated circuit, wherein the semiconductor integrated circuits according to claim 8 are connected in series.

11. A semiconductor integrated circuit, wherein the semiconductor integrated circuits according to claim 9 are connected in parallel.
